(19) United States
(12) Patent Application Publication
(10) Pub. No.: US 2023/0154822 A1
(43) Pub. Date: May 18, 2023

(54) Semiconductor Device and Method for Manufacturing The Same

(71) Applicant: Nippon Telegraph and Telephone Corporation, Tokyo (JP)

(72) Inventors: Yusuke Araki, Musashino-shi, Tokyo (JP); Hideaki Matsuzaki, Musashino-shi, Tokyo (JP); Yuta Shiratori, Musashino-shi, Tokyo (JP)

(21) Appl. No.: 17/922,944

(22) PCT Filed: May 20, 2020
(86) PCT No.: PCT/JP2020/019912

§ 371 Date: Nov. 2, 2022

(51) Int. Cl. H01L 23/367; H01L 23/31; H01L 25/065; H01L 23/00; H01L 21/56; H01L 21/48; H01L 23/538

(52) U.S. Cl. CPC H01L 23/3675; H01L 23/3107; H01L 25/0655; H01L 24/73; H01L 24/16; H01L 24/24; H01L 21/565; H01L 21/568; H01L 21/4882; H01L 23/5386; H01L 2224/16225; H01L 2224/73209; H01L 2224/24226; H01L 2924/182; H01L 2924/186; H01L 2924/1611; H01L 2924/16195; H01L 2924/16235; H01L 2924/16251; H01L 2924/1011

(57) ABSTRACT

A semiconductor device includes a first heat sink formed in contact with a back surface of a first semiconductor chip, and a second heat sink formed in contact with a back surface of a second semiconductor chip. The first heat sink is made of a material with larger thermal conductivity than that of the first semiconductor chip and has a heat dissipation surface exposed from the mold resin layer to the outside. The second heat sink is made of a material with larger thermal conductivity than that of the second semiconductor chip and has a heat dissipation surface exposed from the mold resin layer to the outside.

### TECHNICAL FIELD

The present invention relates to a semiconductor device and a method for producing the same.

### BACKGROUND ART

For the further development of electronics, there is a need to increase the scale of integration without miniaturization, to integrate semiconductor chips with different materials for higher functionality, and to transmit high-frequency signals for faster processing. WLP (Wafer Level Package) is attracting attention as a technology that can solve these problems.

WLP is a package in which a plurality of semiconductor chips are encapsulated on a wafer scale with mold resin and then connected to each other by interconnects formed using a production apparatus similar to that used in the semiconductor production process.

A method for producing a WLP is described in NPL 1, for example. First, an adhesive sheet is disposed on a support substrate, and a semiconductor chip is mounted on the adhesive sheet using a chip transfer machine. Next, the semiconductor chip is embedded in a mold resin layer on the support substrate (adhesive sheet) and encapsulated with the mold resin to form a pseudo-wafer (mold layer). Thereafter, the adhesive sheet is peeled off to remove the support substrate. In this state, the support substrate side of the semiconductor chip is exposed from the mold resin layer. An interconnect layer to be connected to the semiconductor chip is formed using a build-up method on the exposed circuit surface in this pseudo-wafer. Note that this interconnect layer is referred to as a redistribution layer in NPL 1.

WLP allows semiconductor chips to be encapsulated with mold resin regardless of their material or shape, enabling integration of semiconductor chips of different materials. In addition, with the improvement of patterning accuracy in apparatus for producing semiconductor devices and chip mounting accuracy in chip transfer machines, WLP enables fine and highly accurate interconnection between chips, and allows chips to be connected with the same planar structure as the interconnects within the chips. As a result, WLP enables high-density integration and high-frequency signal transmission. In addition, the above-described method for producing a WLP is batch mounting at the wafer level, thus making it possible to simplify the mounting process.

However, the semiconductor chips are encapsulated with mold resin in the WLP structure, which poses a problem in heat dissipation. The following is a description of small thermal conductivity of the mold resin and difficulty in drastically improving this value.

First, the thermal conductivity of the mold resin used in WLP is typically around 1 W/m K, and is smaller than the value of Si, i.e., a typical semiconductor material chip, which is about 170 W/m K, and the value of copper, i.e., a typical heat sink material, which is about 400 W/m K.

To improve the thermal conductivity of the aforementioned mold resin, adding a filler made of a material with high thermal conductivity to the mold resin can be considered as an example. However, addition of the filler will also affect the thermal expansion coefficient of the mold resin. The thermal expansion coefficient of the mold resin used in WLP needs to be smaller than that of general epoxy resin or the like in order to match the thermal expansion coefficient of the semiconductor chip.

If, for example, the thermal expansion coefficient of the mold resin is larger than the thermal expansion coefficient of the chip to be molded, there is a concern that thermal stress will be generated due to the difference in the thermal expansion coefficient between the members during the fabrication of the aforementioned pseudo-wafer, resulting in warping and cracking of the pseudo-wafer.

As described above, it is difficult to drastically improve the thermal conductivity with the technique of including a filler or the like, due to the constraint of the thermal expansion coefficient. Accordingly, if a semiconductor chip is encapsulated with mold resin, heat generated in the semiconductor chip cannot be diffused, and the temperature of the semiconductor chip may exceed the allowable upper temperature limit.

Against the background of the above-described problems related to heat dissipation of resin mold, techniques for improve the heat dissipation characteristics of the WLP structure have been developed. For example, NPL 2 proposes a semiconductor device with which improvement of the heat dissipation of the WLP structure is attempted. This semiconductor device will be described with reference to FIG. 4. In this semiconductor device, two semiconductor chips 302 and 303 with different thicknesses are encapsulated with a mold resin layer 305 on an interconnect layer 301.

The thickness of the mold resin layer 305 is equal to that of the semiconductor chip 302, which is thicker, and therefore the thicker semiconductor chip 302 is exposed from the mold resin layer 305. A heat sink 307 is disposed immediately above the mold resin layer 305 and the thicker semiconductor chip 302. The heat sink 307 is connected to the semiconductor chip 303 via a heat transfer plate 306.

An integrated circuit 302a of the semiconductor chip 302 is electrically connected to an integrated circuit 303a of the semiconductor chip 303 via an interconnect 301a formed in the interconnect layer 301. Terminals 301b are disposed under the interconnect layer 301, and the interconnect layer 301 is connected (mounted) to a printed board 308 via the terminals 301b.

According to the above structure, heat generated in the semiconductor chip 302 is transferred to the heat sink 307 and is diffused to the atmosphere from the heat sink 307. This configuration can improve heat dissipation of the WLP.

As another example, a semiconductor device with which improvement of heat dissipation in the WLP structure is attempted will be described with reference to FIG. 5 (NPL 2). In this semiconductor device, semiconductor chips 312 and 313 that have the same shape are encapsulated with a mold resin layer 305. The mold resin layer 305 is made thicker than the semiconductor chips 312 and 313 by about 100 μm, and back surfaces of the semiconductor chips 312 and 313 on which a functional circuit (integrated circuit) is not formed are completely covered by the mold resin layer 305.

In this semiconductor device, a heat sink 307 made of metal is disposed on the mold resin layer 305 via a thermal conductive layer 309 made of a thermal conductive material. The thermal conductive layer 309 also functions as an adhesive layer between the mold resin layer 305 and the heat sink 307. The thermal conductivity layer 309 has a thickness of about 40 μm. An interconnect layer 301 layer is provided below the semiconductor chips 312 and 313 and the mold resin layer 305.

An integrated circuit 312a of the semiconductor chip 312 is electrically connected to an integrated circuit 313a of the semiconductor chip 313 via an interconnect 301a formed in the interconnect layer 301. Terminals 301b are disposed under the interconnect layer 301, and the interconnect layer 301 is connected (mounted) to a printed board 308 via the terminals 301b.

This semiconductor device uses a mold resin layer 305 with relatively high thermal conductivity, the value of which is 3.1 W/m K. The heat sink 307 is made of copper. According to the above structure, thermal and electrical crosstalk is suppressed by the mold resin layer 305, while heat generated in the semiconductor chips is diffused to the atmosphere from the heat sink 307 via the mold resin layer 305 and the thermal conductive material. This configuration can improve heat dissipation of the WLP.

Both of the above-described methods for producing a semiconductor device include a step in which the heat sink is attached to each package, in addition to the usual method for producing a WLP.

### CITATION LIST

### Non Patent Literature

[NPL 1] John H. Lau, “Recent Advances and Trends in Fan-Out Wafer/Panel-Level Packaging”, Journal of Electronic Packaging, vol. 141, 040801. 2019.
[NPL 2] A. Cardoso et al., “Thermally Enhanced FOWLP-Development of a Power-eWLB Demonstrator”, European Microelectronics Packaging Conference Friedrichshafen, ISBN 978-0-9568086-2-2, 2015

### SUMMARY OF THE INVENTION

### Technical Problem

In the semiconductor device described with reference to FIG. 4, the semiconductor chip 302 and the heat sink 307 are directly connected, and the semiconductor chip 303 and the heat sink 307 are connected via the heat transfer plate 306. This configuration can improve heat dissipation deriving from the encapsulation with the mold resin layer 305.

However, the semiconductor chips 302 and 303 are thermally and electrically connected via the heat sink 307 and the heat transfer plate 306. For this reason, if, for example, a semiconductor chip 302 that generates more heat and a semiconductor chip 303 that generates less heat are mounted, heat is transferred from the semiconductor chip 302 that generates more heat to the semiconductor chip 303 that generates less heat. As a result, the temperature of the semiconductor chip 303 that generates less heat may exceed the allowable upper temperature limit. Moreover, the potentials of the circuit surfaces become equal depending on the conductivity of the semiconductor chips. Such thermal and electrical crosstalk may lead to unexpected defects.

In the semiconductor device described with reference to FIG. 5, the semiconductor chips 312 and 313 and the heat sink 307 are connected via the mold resin layer 305. With this configuration, thermal and electrical crosstalk is suppressed by the mold resin layer 305. Meanwhile, the back surfaces of the semiconductor chips 312 and 313 are encapsulated with the mold resin layer 305, which limits the effect of improving heat dissipation.

In NPL 2, it is attempted to increase in heat dissipation efficiency from the semiconductor chips 312 and 313 to the heat sink 307 by increasing the thermal conductivity of the mold resin layer 305. However, the thermal conductivity of the mold resin layer 305 used in WLP is difficult to drastically increase, as mentioned above. In the discussion in NPL 2, the thermal conductivity of the mold resin layer 305 is 3.1 W/m K at the highest, which is not as high as that of Si, which is a semiconductor material, or copper used for heat sinks. Such a mold resin layer 305 with small thermal conductivity is still a bottleneck for heat dissipation. Thus, it has been difficult to suppress thermal and electrical crosstalk while improving heat dissipation.

The present invention has been made to solve the foregoing problems, and an object of the invention is to make it possible to suppress thermal and electrical crosstalk while improving heat dissipation.

### Means for Solving the Problem

A semiconductor device according to the present invention includes: an interconnect layer with an interconnect formed thereon; a first semiconductor chip and a second semiconductor chip disposed on the interconnect layer and molded with a mold resin layer made of a mold resin; a first integrated circuit formed on a main surface of the first semiconductor chip, the main surface facing toward the interconnect layer, the first integrated circuit being connected to the interconnect; a second integrated circuit formed on a main surface of the second semiconductor chip, the main surface facing toward the interconnect layer, the second integrated circuit being connected to the interconnect; a first heat sink formed in contact with a back surface of the first semiconductor chip and made of a material having a larger heat conductivity than that of the first semiconductor chip, the first heat sink having a heat dissipation surface exposed from the mold resin layer to an outside; and a second heat sink formed in contact with a back surface of the second semiconductor chip and made of a material having a larger heat conductivity than that of the second semiconductor chip, the second heat sink having a heat dissipation surface exposed from the mold resin layer to the outside.

A method for producing a semiconductor device according to the present invention includes: a first step of fixing a first heat sink made of a material having a larger heat conductivity than that of a first semiconductor chip with a first integrated circuit formed on a main surface thereof, in contact with a back surface of the first semiconductor chip; a second step of fixing a second heat sink made of a material having a larger heat conductivity than that of a second semiconductor chip with a second integrated circuit formed on a main surface thereof, in contact with a back surface of the second semiconductor chip; a third step of fixing the first semiconductor chip with the first heat sink fixed thereto onto a support substrate, with a surface with the first integrated circuit of the first semiconductor chip facing the support substrate; a fourth step of fixing the second semiconductor chip with the second heat sink fixed thereto onto the support substrate, with a surface with the second integrated circuit of the second semiconductor chip facing the support substrate; a fifth step of molding, on the support substrate, the first semiconductor chip with the first heat sink fixed thereto and the second semiconductor chip with the second heat sink fixed thereto, using a mold resin, to form a mold resin layer; a sixth step of separating the mold resin layer from the support substrate; a seventh step of, after separating the mold resin from the support substrate, disposing the first semiconductor chip and the second semiconductor chip on an interconnect layer having an interconnect and connecting the first integrated circuit and the second integrated circuit to the interconnect such that the first semiconductor chip and the second semiconductor chip are is a state of being molded with the mold resin layer on the interconnect layer; and an eighth step of exposing a heat dissipation surface of the first heat sink and a heat dissipation surface of the second heat sink from the mold resin layer to an outside.

### Effects of the Invention

As described above, according to the present invention, a heat sink with a heat dissipation surface exposed from the mold resin layer to the outside is provided in contact with the back surface of each semiconductor chip. It is, therefore, possible to suppress thermal and electrical crosstalk while improving heat dissipation.

### BRIEF DESCRIPTION OF DRAWINGS

FIG. 1 is a cross-sectional view showing a configuration of a semiconductor device according to an embodiment of the present invention.

FIG. 2A is a cross-sectional view showing the state of the semiconductor device in an intermediate step for illustrating a method for producing a semiconductor device according to the embodiment of the present invention.

FIG. 2B is a cross-sectional view showing the state of the semiconductor device in an intermediate step for illustrating the method for producing a semiconductor device according to the embodiment of the present invention.

FIG. 2C is a cross-sectional view showing the state of the semiconductor device in an intermediate step for illustrating the method for producing a semiconductor device according to the embodiment of the present invention.

FIG. 2D is a cross-sectional view showing the state of the semiconductor device in an intermediate step for illustrating the method for producing a semiconductor device according to the embodiment of the present invention.

FIG. 2E is a cross-sectional view showing the state of the semiconductor device in an intermediate step for illustrating the method for producing a semiconductor device according to the embodiment of the present invention.

FIG. 2F is a cross-sectional view showing the state of the semiconductor device in an intermediate step for illustrating the method for producing a semiconductor device according to the embodiment of the present invention.

FIG. 2G is a cross-sectional view showing the state of the semiconductor device in an intermediate step for illustrating the method for producing a semiconductor device according to the embodiment of the present invention.

FIG. 2H is a cross-sectional view showing the state of the semiconductor device in an intermediate step for illustrating the method for producing a semiconductor device according to the embodiment of the present invention.

FIG. 3 is a cross-sectional view showing another configuration of the semiconductor device according to the embodiment of the present invention.

FIG. 4 is a cross-sectional view showing a configuration of a semiconductor device with a WLP structure.

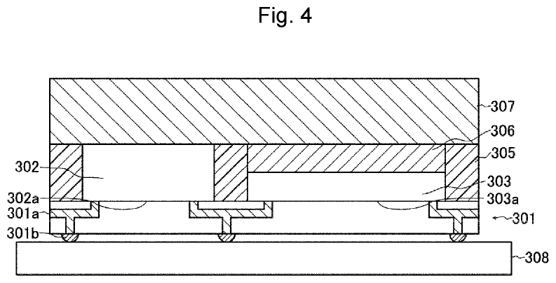

FIG. 5 is a cross-sectional view showing a configuration of a semiconductor device with a WLP structure.

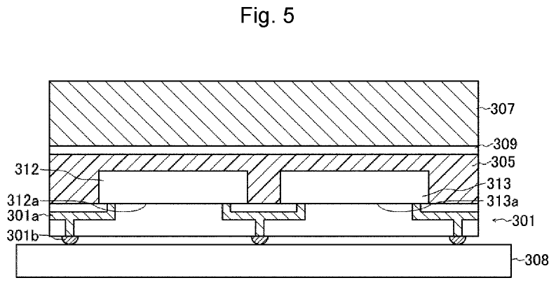

### DESCRIPTION OF EMBODIMENTS

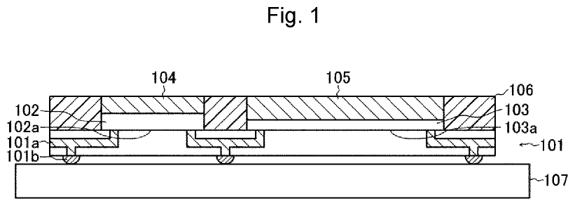

Hereinafter, a semiconductor device according to an embodiment of the present invention will be described with reference to FIG. 1. This semiconductor device includes an interconnect layer 101, and a first semiconductor chip 102 and a second semiconductor chip 103 that are disposed on the interconnect layer 101.

An interconnect 101a, which is made of metal, is formed on the interconnect layer 101. A first integrated circuit 102a that is electrically connected to the interconnect 101a is formed on a main surface of the first semiconductor chip 102 that faces toward the interconnect layer 101 side. A second integrated circuit 103a that is electrically connected to the interconnect 101a is formed on a main surface of the second semiconductor chip 103 that faces toward the interconnect layer 101 side. The first integrated circuit 102a is connected to the second integrated circuit 103a by the interconnect 101a. The first semiconductor chip 102 and the second semiconductor chip 103 are molded on the interconnect layer 101 by a mold resin layer 106, which is made of mold resin.

The semiconductor device also includes a first heat sink 104 that is formed in contact with a back surface of the first semiconductor chip 102, and a second heat sink 105 that is formed in contact with a back surface of the second semiconductor chip 103. The first heat sink 104 is made of a material with larger thermal conductivity than that of the first semiconductor chip 102, and has a heat dissipation surface exposed from the mold resin layer 106 to the outside. The second heat sink 105 is made of a material with larger thermal conductivity than that of the second semiconductor chip 103, and has a heat dissipation surface exposed from the mold resin layer 106 to the outside. The heat dissipation surfaces are opposite surfaces to the surfaces on the semiconductor chip side.

The first heat sink 104 and the second heat sink 105 may be made of an insulating material such as silicon carbide, aluminum nitride, beryllium oxide, or diamond, for example. The first heat sink 104 and the second heat sink 105 may also be made of metal such as aluminum, copper, or gold.

In the semiconductor device, the total thickness of the first semiconductor chip 102 and the first heat sink 104, the total thickness of the second semiconductor chip 103 and the second heat sink 105, and the thickness of the mold resin layer 106 are equal to each other. As a result, the heat dissipation surface of the first heat sink 104 and the heat dissipation surface of the second heat sink 105 are exposed from the mold resin layer 106 to the outside.

Although the first semiconductor chip 102 and the second semiconductor chip 103 have different thicknesses in the example shown in FIG. 1, the first semiconductor chip 102 and the second semiconductor chip 103 may alternatively have different thicknesses. The material of the first semiconductor chip 102 may be different from the material of the second semiconductor chip 103. The thicknesses of the first heat sink 104 and the second heat sink 105 may be set as appropriate.

In the semiconductor device, a terminal 101b is formed under the interconnect layer 101, and the interconnect layer 101 is electrically connected (mounted) to a printed board 107 via the terminal 101b. This example describes a face-down process for WLP and secondary mounting on the printed board 107. However, the effect of the present invention can also be obtained for other processes such as a face-up process for WLP and designs without secondary mounting.

With the semiconductor device according to the above-described embodiment, first, the first semiconductor chip 102 is thermally and electrically separated from the second semiconductor chip 103 by the mold resin layer 106 in the surface direction of the interconnect layer 101. Further, the first heat sink 104 connected to the first semiconductor chip 102 is thermally and electrically separated from the second heat sink 105 connected to the second semiconductor chip 103 by the mold resin layer 106. For this reason, the first semiconductor chip 102 is thermally separated from the second semiconductor chip 103. No matter what the conductivity of the body of each semiconductor chip is, the potentials of the surfaces on which the integrated circuits are formed do not become equal.

In addition, with the semiconductor device according to the embodiment, heat of the first semiconductor chip 102 is dissipated from a heat dissipation surface capable of coming into contact with outside air, via the first heat sink 104 that is directly connected to the first semiconductor chip 102. Similarly, heat of the second semiconductor chip 103 is dissipated from a heat dissipation surface capable of coming into contact with outside air, via the second heat sink 105 that is directly connected to the second semiconductor chip 103. As a result, heat dissipation deriving from the mold resin layer 106 is improved.

As a result, with the semiconductor device according to the embodiment, it is possible to suppress thermal and electrical crosstalk while improving heat dissipation.

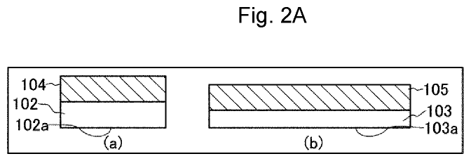

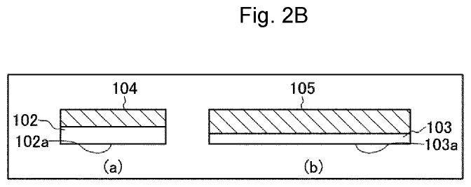

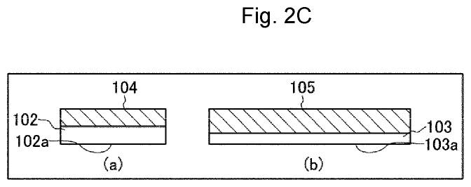

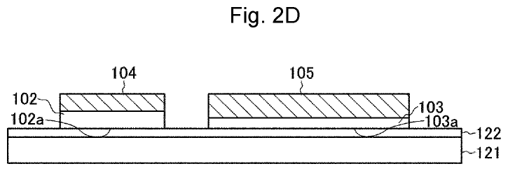

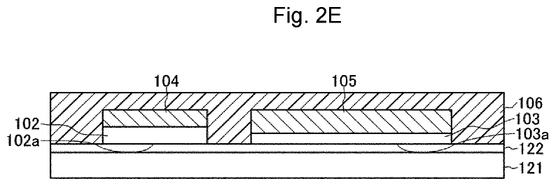

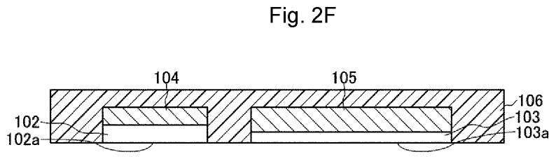

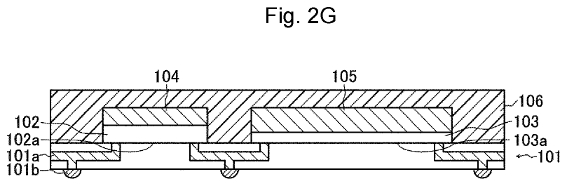

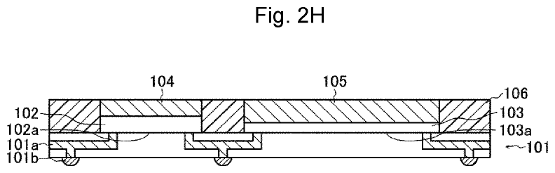

Next, a method for producing a semiconductor device according to the present invention will be described with reference to FIGS. 2A to 2H.

First, as shown as (a) in FIGS. 2A to 2C, the first heat sink 104 that is made of a material with larger thermal conductivity than that of the first semiconductor chip 102 is fixed in contact with the back surface of the first semiconductor chip 102 with the first integrated circuit 102a formed on its main surface (first step). Also, as shown as (b) in FIGS. 2A to 2C, the second heat sink 105 that is made of a material with larger thermal conductivity than that of the second semiconductor chip 103 is fixed in contact with the back surface of the second semiconductor chip 103 with the second integrated circuit 103a formed on its main surface (second step).

For example, the above steps can be carried out by bonding a first heat sink wafer to serve as the first heat sink 104 to a first wafer to form the first semiconductor chip 102, and bonding a second heat sink wafer to serve as the second heat sink 105 to a second wafer to form the second semiconductor chip 103. A known semiconductor wafer bonding technique (e.g., surface activated bonding) can be used in the above bonding. Next, the first and second wafers are thinned and polished so that the thickness of the first wafer with the first heat sink wafer bonded thereto is equal to the thickness of the second wafer with the second heat sink wafer bonded thereto.

Next, semiconductor layers are formed on the first and second wafers by means of a known crystal growth technique. A desired functional circuit is also formed by implementing a known semiconductor process to these semiconductor layers. A plurality of first integrated circuits 102a are formed on the first wafer, and a plurality of second integrated circuits 103a are formed on the second wafer (FIG. 2B). Thereafter, the first heat sink 104 is fixed to the back surface of the first semiconductor chip 102 with the first integrated circuits 102a formed on the main surface thereof, as shown as (a) in FIG. 2C, by dicing the wafers, for example. Also, the second heat sink 105 is fixed to the back surface of the second semiconductor chip 103 with the second integrated circuits 103a formed on the main surface thereof, as shown as (b) in FIG. 2C.

Next, the surface of the first semiconductor chip 102 cut out into a chip on which a first integrated circuit 102a is formed is attached and fixed to an adhesive layer 122 fixed onto a support substrate 121, as shown in FIG. 2D. Further, the surface of the second semiconductor chip 103 cut out into a chip on which a second integrated circuit 103a is formed is attached and fixed to the adhesive layer 122 (third and fourth steps). Although the figures show one pair of the first semiconductor chip 102 and the second semiconductor chip 103, more than one pairs can be simultaneously fixed (mounted) onto the support substrate 121, for example.

The support substrate 121 need only have a size corresponding to the semiconductor production apparatus used when the later-described interconnect layer 101 is formed. The material of the support substrate 121 can be semiconductor such as silicon, glass, resin, or metal, for example. The adhesive 122 can be made of a material capable of withstanding the temperature at which the later-described mold resin layer 106 is formed.

Next, the first semiconductor chip 102 to which the first heat sink 104 is fixed and the second semiconductor chip 103 to which the second heat sink 105 is fixed are molded with mold resin on the support substrate 121 to form the mold resin layer 106, as shown in FIG. 2E (fifth step). The mold resin layer 106 can be formed by forming a layer of the mold resin and curing the formed layer of the mold resin by means of a known compression mold method or transfer mold method, for example.

Next, the mold resin layer 106 is separated from the support substrate 121 (sixth step), and the surface on which the integrated circuits are formed is exposed, as shown in FIG. 2F. For example, the mold resin layer 106 can be separated from the support substrate 121 by peeling the adhesive layer 122. For example, a method that does not degrade characteristics of the integrated circuits such as a laser peeling method, a thermal peeling method, a mechanical peeling method, or a solvent peeling method can be selected.

Next, after the mold resin is separated from the support substrate 121, the first semiconductor chip 102 and the second semiconductor chip 103 are formed on the interconnect layer 101 including the interconnect 101a, as shown in FIG. 2G. The first integrated circuit 102a and the second integrated circuit 103a are connected to the interconnect 101a. Further, a state is entered where the first semiconductor chip 102 and the second semiconductor chip 103 are molded with the mold resin layer 106 on the interconnect layer 101 (seventh step).

For example, the interconnect layer 101 can be formed on the first semiconductor 102 and the second semiconductor chip 103 that are molded with the mold resin layer 106, by means of the build-up method. For example, after the first semiconductor chip 102 and the second semiconductor chip 103 are molded with the mold resin layer 106, the interconnect layer 101 can be obtained by forming a metal layer on the mold resin layer 106 by means of evaporation or plating, for example, and patterning the metal layer to form the interconnect 101a. Further, the terminal 101b to be connected to the interconnect 101a is formed on the interconnect layer 101 by means of solder bumps or the like, for example. Although the figures show one pair of the first semiconductor chip 102 and the second semiconductor chip 103, more than one pairs can be simultaneously molded with the mold resin layer 106, for example.

Next, the heat dissipation surface of the first heat sink 104 and the heat dissipation surface of the second heat sink 105 are exposed from the mold resin layer 106 to the outside, as shown in FIG. 2H (eighth step). For example, the heat dissipation surface of the first heat sink 104 and the heat dissipation surface of the second heat sink 105 are exposed by mechanically polishing (grinding and polishing), with a grinder or the like, the surface of the interconnect layer 101 on the side where the heat sinks are deposed. Thereafter, pairs of the first semiconductor chip 102 and the second semiconductor chip 103 are separated into individual pieces using a dicing device. Thereafter, the semiconductor device shown in FIG. 1 is obtained by mounting a package of the separated piece of a pair of the first semiconductor chip 102 and the second semiconductor chip 103 on the printed board 107 via the terminal 101b. If, for example, solder bumps are used, the mounting can be realized using known reflow technology.

According to the above-described embodiment, first, the first semiconductor chip 102 is separated from the second semiconductor chip 103 by the mold resin layer 106. Thus, thermal and electrical crosstalk between the first heat sink 104 and the second heat sink 105 is suppressed.

In addition, heat generated from the first integrated circuit 102a and the second integrated circuit 103a of the first semiconductor chip 102 and the second semiconductor chip 103 is transferred from the bodies of the semiconductor chips to the first heat sink 104 and the second heat sink 105 that have higher heat conductivity, and is then dissipated to the atmosphere. Thus, according to the embodiment, heat dissipation can be improved since the mold resin layer 106 having significantly low heat conductivity is not present in the heat dissipation path.

In addition, the first heat sink 104 and the second heat sink 105 ensure the mechanical strength of the semiconductor device according to the present embodiment. Therefore, the semiconductor portions of the semiconductor chips that have low thermal conductivity can be extremely thinned without breaking the device due to lack of mechanical strength during the production process, thus making it possible to improve heat dissipation efficiency.

In the method for producing a semiconductor device according to the present embodiment, dicing can be performed after bonding heat sinks of the same size to a semiconductor wafer. As a result, semiconductor chips equipped with the heat sinks in advance can be made into WLPs, and the mounting process can be shortened in terms of time without having to install a heat sink to each package. The advantage of the method for producing a WLP is that WLPs can be produced in bulk at the wafer level. However, when a heat sink is attached, it was conventionally necessary to attach it to each package, and the heat sink attachment process led to an increase in the time required for the mounting process. In contrast, the above-described embodiment makes it possible to both suppress thermal and electrical crosstalk and shorten the time required for the mounting process, while improving heat dissipation.

When it is attempted to expose the backside of each semiconductor chip in a WLP in which two semiconductor chips including different semiconductors are encapsulated, the mold resin and the semiconductor chips are scraped. In this case, it is necessary to give consideration to physical property values of the mold resin and the semiconductor chips in regard to grinding conditions. For example, the mold resin and two types of semiconductor chips of dissimilar materials must be conditioned for grinding for each combination of semiconductor chips. In contrast, according to the embodiment, the grinding conditions are determined for the combination of the mold resin and a specific type of heat sink. Therefore, the grinding conditions do not depend on the semiconductor chips, which has the advantage of making it easier to set grinding conditions.

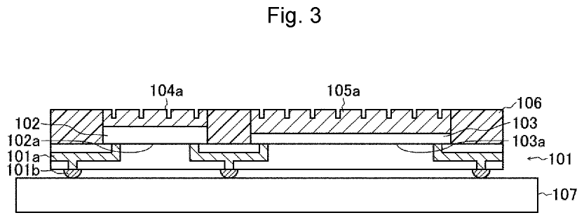

A configuration with an uneven structure formed on the heat dissipation surface of the first heat sink 104a and the heat dissipation surface of the second heat sink 105a as shown in FIG. 3 may alternatively be employed. For example, an uneven structure can be formed on the heat dissipation surface of the first heat sink 104a and the heat dissipation surface of the second heat sink 105a by partially etching these surfaces. The surface area of each heat dissipation surface can be increased by thus forming the uneven structure, thus making it possible to further improve heat dissipation efficiency.

As described above, according to the present invention, a heat sink with a heat dissipation surface exposed from the mold resin layer to the outside is provided in contact with the back surface of each semiconductor chip. It is, therefore, possible to suppress thermal and electrical crosstalk while improving heat dissipation.

Note that the present invention is not limited to the above-described embodiment, and it is apparent that many modifications and combinations can be carried out by those with common knowledge in this field within the technical idea of the present invention.

### REFERENCE SIGNS LIST

101 Interconnect layer
101a Interconnect
101b Terminal
102 First semiconductor chip
102a First integrated circuit
103 Second semiconductor chip
103a Second integrated circuit
104 First heat sink
105 Second heat sink
106 Mold resin layer
107 Printed board

1. A semiconductor device comprising:
an interconnect layer with an interconnect formed thereon;
a first semiconductor chip and a second semiconductor chip disposed on the interconnect layer and molded with a mold resin layer made of a mold resin;
a first integrated circuit formed on a main surface of the first semiconductor chip, the main surface facing toward the interconnect layer, the first integrated circuit being connected to the interconnect;
a second integrated circuit formed on a main surface of the second semiconductor chip, the main surface facing toward the interconnect layer, the second integrated circuit being connected to the interconnect;
a first heat sink formed in contact with a back surface of the first semiconductor chip and made of a material having a larger heat conductivity than that of the first semiconductor chip, the first heat sink having a heat dissipation surface exposed from the mold resin layer to an outside; and
a second heat sink formed in contact with a back surface of the second semiconductor chip and made of a material having a larger heat conductivity than that of the second semiconductor chip, the second heat sink having a heat dissipation surface exposed from the mold resin layer to the outside.

2. The semiconductor device according to claim 1, wherein
a total thickness of the first semiconductor chip and the first heat sink is the same as a total thickness of the second semiconductor chip and the second heat sink.

3. The semiconductor device according to claim 1, wherein
a material of the first semiconductor chip is different from a material of the second semiconductor chip.

4. The semiconductor device according to claim 1, wherein
the heat dissipation surface of the first heat sink and the heat dissipation surface of the second heat sink each have an uneven structure.

5. A method for producing a semiconductor device, the method comprising:
a first step of fixing a first heat sink made of a material having a larger heat conductivity than that of a first semiconductor chip with a first integrated circuit formed on a main surface thereof, in contact with a back surface of the first semiconductor chip;
a second step of fixing a second heat sink made of a material having a larger heat conductivity than that of a second semiconductor chip with a second integrated circuit formed on a main surface thereof, in contact with a back surface of the second semiconductor chip;
a third step of fixing the first semiconductor chip with the first heat sink fixed thereto onto a support substrate, with a surface with the first integrated circuit of the first semiconductor chip facing the support substrate;
a fourth step of fixing the second semiconductor chip with the second heat sink fixed thereto onto the support substrate, with a surface with the second integrated circuit of the second semiconductor chip facing the support substrate;
a fifth step of molding, on the support substrate, the first semiconductor chip with the first heat sink fixed thereto and the second semiconductor chip with the second heat sink fixed thereto, using a mold resin, to form a mold resin layer;
a sixth step of separating the mold resin layer from the support substrate;
a seventh step of, after separating the mold resin from the support substrate, disposing the first semiconductor chip and the second semiconductor chip on an interconnect layer having an interconnect and connecting the first integrated circuit and the second integrated circuit to the interconnect such that the first semiconductor chip and the second semiconductor chip are is a state of being molded with the mold resin layer on the interconnect layer; and
an eighth step of exposing a heat dissipation surface of the first heat sink and a heat dissipation surface of the second heat sink from the mold resin layer to an outside.

6. The method for producing a semiconductor device according to claim 5, wherein
in the eighth step, the heat dissipation surface of the first heat sink and the heat dissipation surface of the second heat sink are exposed from the mold resin layer to the outside by grinding and polishing the mold resin layer from the heat dissipation surface side of the first heat sink and the second heat sink.

7. The semiconductor device according to claim 2, wherein
a material of the first semiconductor chip is different from a material of the second semiconductor chip.

8. The semiconductor device according to claim 2, wherein
the heat dissipation surface of the first heat sink and the heat dissipation surface of the second heat sink each have an uneven structure.

9. The semiconductor device according to claim 3, wherein
the heat dissipation surface of the first heat sink and the heat dissipation surface of the second heat sink each have an uneven structure.
